(19) United States
(12) Patent Application Publication
(10) Pub. No.: US 2025/0344346 A1
(43) Pub. Date: Nov. 6, 2025

(54) LIQUID COOLING SYSTEM WITH LEAK PROTECTION AND METHOD FOR COOLING LIQUID LEAK PROTECTION

(71) Applicant: Wiwynn Corporation, New Taipei City (TW)

(72) Inventors: Chia-Hung Yen, New Taipei City (TW); TINGYA LIAO, New Taipei City (TW); Kun Hsien Lee, New Taipei City (TW); Cheng-Kuang HSIEH, New Taipei City (TW)

(21) Appl. No.: 19/189,330

(22) Filed: Apr. 25, 2025

Related U.S. Application Data
(60) Provisional application No. 63/641,986, filed on May 3, 2024.

(30) Foreign Application Priority Data
Jan. 23, 2025 (TW) 114103108

(51) Int. Cl. H05K 7/20

(52) U.S. Cl. CPC H05K 7/20272; H05K 7/20254; H05K 7/20263; H05K 7/20281; H05K 7/20772

(57) ABSTRACT

The present disclosure proposes a liquid cooling system with leak protection and method for cooling liquid leak protection. The liquid cooling system is adapted to a server system including a rack and a server. The liquid cooling system includes: a cooling distribution unit (CDU), a liquid detector, a local leak management device and a central leak management device. The CDU distributes coolant to a cold plate disposed inside the server through a manifold and a water valve. The liquid detector is disposed inside the sever and configured to generate a server leakage event. The local leak management device is disposed inside the rack and configured to control the sever to shutdown after data archiving, close the water valve and output a server leak notification after receiving the event. The central leak management device controls the CDU to reduce a flow rate distributed to the cold plate based on the notification.

### CROSS-REFERENCE TO RELATED APPLICATIONS

This non-provisional application claims priority under 35 U.S.C. § 119(a) on Patent Application No(s). 63/641,986 filed in the U.S. on May 3, 2024 and No(s). 114103108 filed in Republic of China (Taiwan) on Jan. 23, 2025, the entire contents of which are hereby incorporated by reference.

### BACKGROUND

### 1. Technical Field

This disclosure relates to a liquid cooling system with leakage protection and a method for cooling liquid leak protection.

### 2. Related Art

With the rapid growth of computing capability demand, efficient heat dissipation and energy conservation have become topics receiving increasing attention. Currently, liquid cooling technology is gradually being applied to data centers and high-performance computing systems. A centralized data platform primarily focuses on monitoring the health status and temperature of equipment of these systems to achieve real-time operating status monitoring. Therefore, the data platform can provide real-time data such as system temperature, flow rate, and pressure, offering critical support for the normal operation of the system.

However, currently and mostly, the data platform monitors the operating status of liquid cooling technology and triggers an alarm when a temperature anomaly or malfunction occurs, but manual intervention for repair or adjustment is still required. In addition, existing mitigation solutions are dispersed across monitoring subsystems within servers and data center facilities. These subsystems operate independently and lack effective coordination, resulting in slower response speed when issues arise. Moreover, the mitigation solutions are neither integrated nor consistent, making it difficult to enhance overall system reliability and efficiency.

### SUMMARY

It is therefore an objective of the present disclosure to provide a liquid cooling system with leakage protection and a method for cooling liquid leak protection.

A liquid cooling system with leakage protection according to an embodiment of the present disclosure is applicable to a server system, the server system comprises a rack and a server disposed within the rack, and the liquid cooling system comprises: a cooling distribution unit, a first liquid detector, a local leakage management device, and a central leakage management device. The cooling distribution unit is configured to distribute coolant to a cold plate via a manifold and a water valve, wherein the cold plate is disposed within the server and configured to cool the server. The first liquid detector is disposed within the server and configured to generate a server leakage event. The local leakage management device is disposed within the rack, connected to the first liquid detector, and configured to control the server to shut down after data archiving, close the water valve, and output a server leakage notification upon receiving the server leakage event. The central leakage management device is connected to the local leakage management device and configured to control the cooling distribution unit to reduce a flow rate distributed to the cold plate according to the server leakage notification.

A liquid cooling system with leakage protection according to an embodiment of the present disclosure is applicable to a server system, the server system comprises a rack and a server disposed within the rack, and the liquid cooling system comprises: a pumping unit, a first liquid detector, and a local leakage management device. The pumping unit is disposed within the rack, and configured to distribute coolant to a cold plate via a manifold and a water valve, wherein the cold plate is disposed within the server and configured to cool the server. The first liquid detector is disposed within the server and configured to detect a server leakage event. The local leakage management device is disposed within the rack, connected to the first liquid detector, and configured to control the server to shut down after data archiving, close the water valve, and control the pumping unit to reduce the flow rate distributed to the cold plate upon receiving the server leakage event.

A coolant leakage protection method according to an embodiment is applicable to a server system, the server system comprises a rack and a server disposed within the rack, and the coolant leakage protection method comprises: controlling the server to shut down after data archiving, close a water valve of the server and output a server leakage notification upon detecting a server leakage event; and reducing a flow rate distributed to a cold plate disposed within the server according to the server leakage notification.

The liquid cooling system with leakage protection and method for cooling liquid leak protection of the present disclosure have the following features: (1) automated mitigation mechanism that reduces the need for manual intervention and improves the system's self-protection capability to extend the lifespan of the server system; (2) protection of client's data asset: the automated mitigation mechanism can minimize hardware damage under leakage situation, promptly notify the client and the machine to perform data archiving, thereby extending the equipment's lifespan; and (3) the statuses of all components may be integrated through the setup of the local leak management device and the central leak management device, and in the event of a coolant leakage, the corresponding protective measures may be executed with the shortest delay.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a block diagram of a liquid cooling system with leakage protection according to a first embodiment of the present disclosure;

FIG. 2 is a block diagram of a liquid cooling system with leakage protection according to a second embodiment of the present disclosure;

FIG. 3 is a block diagram of a liquid cooling system with leakage protection and a plurality of server systems according to a third embodiment of the present disclosure;

FIG. 4 is a block diagram of a liquid cooling system with leakage protection and a plurality of server systems according to a fourth embodiment of the present disclosure;

FIG. 5 is a block diagram of a liquid cooling system with leakage protection and a server system according to a fifth embodiment of the present disclosure;

FIG. 6 is a block diagram of a liquid cooling system with leakage protection and a server system according to a sixth embodiment of the present disclosure;

FIG. 7 is a block diagram of a liquid cooling system with leakage protection and a plurality of server systems according to a seventh embodiment of the present disclosure;

FIG. 8 is a block diagram of a server system according to an eighth embodiment of the present disclosure;

FIG. 9 is a flowchart of a coolant leakage protection procedure according to an embodiment of the present disclosure; and

FIG. 10 is a flowchart of a coolant leakage protection procedure according to an embodiment of the present disclosure.

### DETAILED DESCRIPTION

In the following detailed description, for purposes of explanation, numerous specific details are set forth in order to provide a thorough understanding of the disclosed embodiments. According to the description, claims and the drawings disclosed in the specification, one skilled in the art may easily understand the concepts and features of the present invention. The following embodiments further illustrate various aspects of the present invention, but are not meant to limit the scope of the present invention.

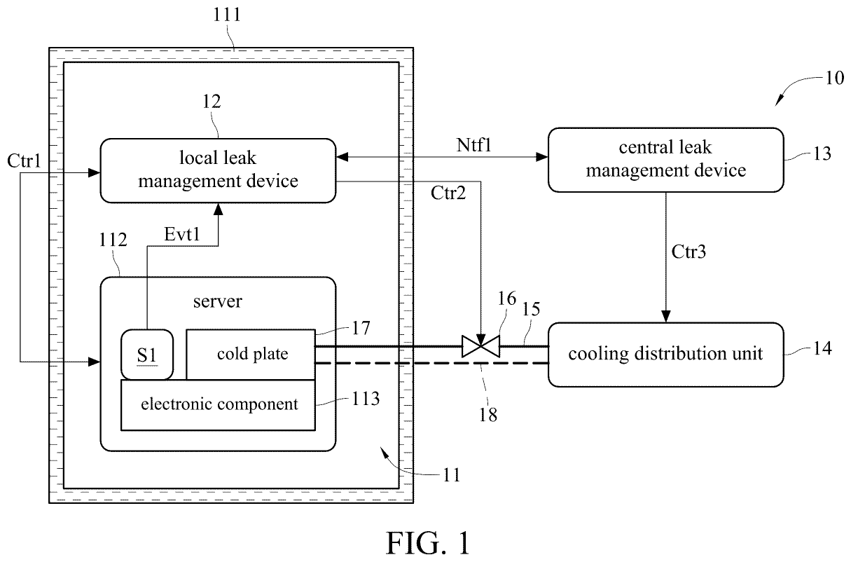

Please refer to FIG. 1, which is a block diagram of a liquid cooling system 10 with leakage protection according to the first embodiment of the present disclosure. The liquid cooling system 10 is configured to provide cooling services to a server system 11, where the server system 11 includes a rack 111 and a server 112 disposed within the rack 111. The liquid cooling system 10 comprises a first liquid detector S1, a local leak management device 12, a central leak management device 13, a cooling distribution unit (hereinafter abbreviated CDU) 14, manifolds 15 and 18, a water valve 16, and a cold plate 17. The manifolds 15 and 18 are connected between the CDU 14 and the cold plate 17, where the manifold 15 is configured to deliver coolant (e.g., cold water) from the CDU 14 to an inlet of the cold plate 17, and the manifold 18 is configured to deliver hot water from an outlet of the cold plate 17 to the CDU 14.

The CDU 14 is configured to distribute coolant to the cold plate 17 via the manifold 15 and the water valve 16, wherein the cold plate 17 is disposed within the server 112 and configured to cool electronic component 113 inside the server 112. The first liquid detector S1 is disposed within the server 112 and configured to detect coolant leakage inside the server 112 to generate a server leakage event Evt1. The local leak management device 12 is disposed within the rack 111 and connected to the first liquid detector S1 and the server 112. The local leak management device 12 is configured to generate a first control signal Ctr1 to control the server 112 to shut down after data archiving, generate a second control signal Ctr2 to close the water valve 16, and generate a server leak notification Ntf1 to the central leak management device 13 according to the server leakage event Evt. The central leak management device 13 is disposed outside the rack 111, connected to the local leak management device 12 and the CDU 14, and configured to output a third control signal Ctr3 to control the CDU 14 to reduce the flow rate of the coolant distributed to the cold plate 17 according to the server leak notification Ntf1. In an embodiment, the CDU 14 reduces the power of the pump to reduce the flow rate of the coolant according to the third control signal Ctr3.

The liquid cooling system 10 with leakage protection of the first embodiment may automatically perform server protection operations and mitigate coolant leakage upon detecting a server leakage event, thereby reducing the need for manual intervention as well as lowering the risk of damage to the server system 11 and the data. Noticeably, under the configuration of the first embodiment, the liquid cooling system 10 may execute the corresponding protective measures with the shortest delay time when a coolant leakage occurs.

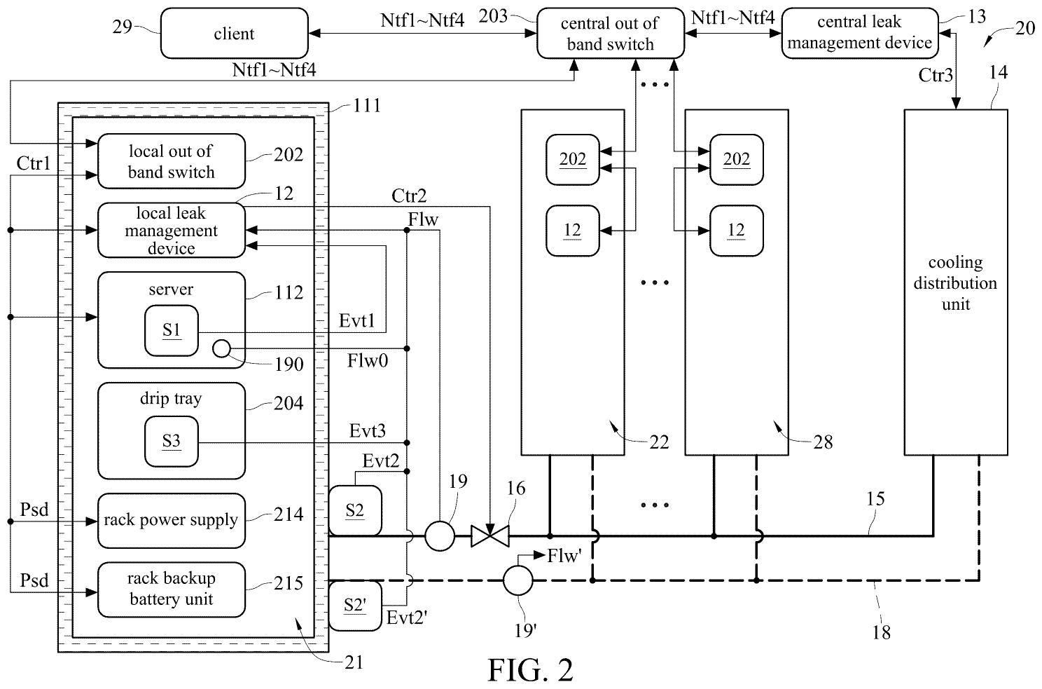

Please refer to FIG. 2, which is a block diagram of a liquid cooling system 20 with leakage protection and the plurality of the server systems 21 . . . 28 according to the second embodiment of the present disclosure. In the embodiments of the present disclosure, substantially identical, similar, or equivalent components are denoted by the same reference numerals. For example, in FIGS. 1 and 2, the server systems 11 and 21 both include the rack 111 and the server 112. The liquid cooling systems 10 and 20 both include the first liquid detector S1, the CDU 14, the manifold 15, the water valve 16, the cold plate 17 (as shown in FIG. 1), and the manifold 18. In FIG. 2, the liquid cooling system 20 further includes a local leak management device 12, a central leak management device 13, a central out of band (hereinafter abbreviated OOB) switch 203, a local OOB switch 202, a plurality of second liquid detectors S2 and S2′, a drip tray 204, a third liquid detector S3, and a flow meter 19. The relative positions between the plurality of components included in the liquid cooling system 20 may be adjusted according to actual requirements and are not limited to the positions shown in FIG. 2.

The liquid cooling system 20 is configured to provide cooling services to the server systems 21 . . . 28. The CDU 14 is disposed outside of the rack 111, connected to the server systems 21 . . . 28, and configured to distribute coolant to the server systems 21 . . . 28. The CDU 14 serves the side-by-side server systems 21 . . . 28, which is also referred to as an “in-row CDU.” The hardware configurations of the server systems 21 . . . 28 may be the same as or different from each other. In other embodiments, the number of server systems serviced by the liquid cooling system 20 is not limited.

The second liquid detector S2 is disposed on the manifold 15 and configured to detect liquid to generate a manifold leakage event Evt2, that is, to detect whether there is a coolant leakage in the manifold 15 at the inlet of the cold plate 17. Another second liquid detector S2′ is disposed on the manifold 18 and configured to detect liquid to generate another manifold leakage event Evt2′, that is, to detect whether there is a coolant leakage in the manifold 18 at the outlet of the cold plate 17. The local leak management device 12 is further configured to generate a first control signal Ctr1 to control the server 112 to enter a standby mode after data archiving, generate a second control signal Ctr2 to close the water valve 16, and output a manifold leakage notification Ntf2 to the central leak management device 13 upon receiving the manifold leakage event Evt2 or Evt2′. The central leak management device 13 is further configured to generate a third control signal Ctr3 to control the CDU 14 to reduce the flow rate of coolant allocated to the cold plate 17 of the server 112 according to the manifold leakage notification Ntf2.

The drip tray 204 may be disposed within the rack 111. The third liquid detector S3 may be disposed within the drip tray 204, connected to the local leak management device 12, and configured to detect liquid to generate a tray leakage event Evt3, that is, to detect whether coolant leakage at the drip tray 204. The local leak management device 12 is further configured to generate a first control signal Ctr1 to control the server 112 to enter the standby mode after data archiving, generate a second control signal Ctr2 to close the water valve 16, and output a tray leakage notification Ntf3 to the central leak management device 13 upon receiving the tray leakage event Evt3. The central leak management device 13 may be further configured to generate a third control signal Ctr3 to control the CDU 14 to reduce the flow rate of the coolant allocated to the cold plate 17 of the server 112 according to the tray leakage notification Ntf3.

In an embodiment, the server leakage event Evt1, the manifold leakage event Evt2, and the tray leakage event Evt3 generated by the first liquid detector S1, the second liquid detector S2, and the third liquid detector S3 are analog signals, and the local leak management device 12 may convert the analog signals into resistance values. Specifically, since the coolant is conductive, when the liquid detector is wetted, the resistance value of the liquid detector decreases (i.e., the conductivity increases). In this case, the local leak management device 12 may determine that there is a coolant leakage when the resistance value is lower than a threshold value; on the contrary, the local leak management device 12 may determine that there is no coolant leakage when the resistance value is greater than or equal to the threshold value. It should be understood that the threshold value corresponding to the liquid detectors may be the same as or different from each other depending on different environmental conditions such as humidity, temperature, pressure, etc., but the present disclosure is not limited thereto.

The server system 21 further includes a rack power supply 214 and a rack backup battery unit 215. The rack power supply 214 is configured to supply power to the electronic component 113 (shown in FIG. 1) and other components within the rack 111. The rack backup battery unit 215 is configured to provide backup power to the electronic component 113 within the rack 111 when the rack power supply 214 fails or stops supplying power. In an embodiment, the local leak management device 12 is further configured to, after outputting at least one of the server leak notification Ntf1, the manifold leakage notification Ntf2, and the tray leakage notification Ntf3, output a stop discharge notification Psd to the rack backup battery unit 215 and the rack power supply 214 to stop discharging. In this case, the power management controller (PM C) and the alternating current (AC) power interface of the server system 21 maintain normal operation, allowing the power distribution and management operations of the server system 21 to run, and enabling other components (such as the power management controller) to continue receiving external power.

The local OOB switch 202 is connected to the local leak management device 12 and configured to forward at least one of the server leak notification Ntf1, the manifold leakage notification Ntf2, and the tray leakage notification Ntf3 from the local leak management device 12 to the central OOB switch 203. In an embodiment, the first liquid detector S1, the second liquid detectors S2, S2′, and the third liquid detector S3 may output the server leakage event Evt1, the manifold leakage event Evt2, and the tray leakage event Evt3 directly to the local leak management device 12, respectively. In another embodiment, the first liquid detector S1, the second liquid detectors S2, S2′, and the third liquid detector S3 may forward the server leakage event, the manifold leakage event, and the tray leakage event to the local leak management device 12 via the local OOB switch 202, respectively.

The central OOB switch 203 is connected between the local OOB switch 202, a client 29, and the central leak management device 13. The central OOB switch 203 is configured to forward at least one of the server leak notification Ntf1, the manifold leakage notification Ntf2, and the tray leakage notification Ntf3 to the client 29 and the central leak management device 13.

The flow meter 19 is disposed within the manifold 15 located outside the server 112 and is configured to generate a flow rate reading Flw of the coolant outside the server 112 to the local leak management device 12. In an embodiment, the flow meter 19′ is disposed within the manifold 18 and is configured to generate a flow rate reading Flw′ to the local leak management device 12. The flow rate reading Flw or Flw′ may significantly decrease when a certain degree of coolant leakage occurs in the manifold 15 or 18. In an embodiment, the liquid cooling system 20 further includes a flow meter 190, disposed within the manifold 15 located inside the server 112, and configured to generate a flow rate reading Flw0 of the coolant inside the server 112 to the local leak management device 12 to improve the immediacy and accuracy of detecting coolant leakage within the server 112. Therefore, the local leak management device 12 may control the server 112 to enter the standby mode after data archiving, close the water valve 16, and output a flow anomaly notification Ntf4 to the central leak management device 13 when the local leak management device 12 determines that at least one of the flow rate readings Flw, Flw′, and Flw0 is lower than a preset flow rate.

The central leak management device 13 may be further configured to control the CDU 14 to reduce the flow rate distributed to the cold plate 17 of the server 112 according to the flow anomaly notification Ntf4. The CDU 14 may reduce the flow rate of the coolant distributed to the cold plate 17 of the server 112 to 0 or a preset lower limit value. In an embodiment, the flow meters 19, 19′, and 190 may be any type of flow meter, such as ultrasonic, variable area, Coriolis, paddle wheel, volumetric, vortex, turbine, differential pressure, laminar, electromagnetic, and thermal mass flow meters.

In an embodiment, the local OOB switch 202 is further configured to forward the flow anomaly notification Ntf4 from the local leak management device 12 to the central OOB switch 203. The central OOB switch 203 is further configured to forward the flow anomaly notification Ntf4 to the client 29 and the central leak management device 13.

The liquid cooling system 20 is configured to serve the client 29. The client 29 is connected to the central leak management device 13 via the central OOB switch 203, and is connected to the local leak management device 12 via the central OOB switch 203 and the local OOB switch 202. The client 29 may be a control console or monitoring center in a data center, or a user's mobile device, a personal computer, etc. In practical application, a user may login to the client 29 and access information provided by the central leak management device 13, the local leak management device 12, and the server 112 via a specific application programming interface (API), said information is such as the leakage notifications Ntf1 . . . Ntf3, the flow anomaly notification Ntf4, the flow rate readings Flw, Flw′, as well as the operating status of the server 112, the rack backup battery unit 215, the rack power supply 214, and the CDU 14.

In an embodiment, the client 29, the central OOB switch 203, the central leak management device 13, the local OOB switch 202, the server 112, the rack power supply 214, and the rack backup battery unit 215 communicate and exchange information with each other through the Ethernet. The central OOB switch 203 and the local OOB switch 202 are local area network (LAN) switches. The central leak management device 13 (or the local leak management device 12) communicates and exchanges information with the CDU 14 through the MODBUS transmission control protocol (TCP). The first liquid detector S1, the second liquid detectors S2, S2′, and the third liquid detector S3 transmit the analog signals corresponding to resistance values to the local leak management device 12 to transmit the server leakage event Evt1, the manifold leakage event Evt2, and the tray leakage event Evt3. The flow meters 19 and 19′ transmit the analog signals corresponding to the current values to the local leak management device 12, respectively, to transmit the flow rate readings Flw and Flw′. The flow meter 190 transmits an analog signal corresponding to a specific frequency to the local leak management device 12 to transmit the flow rate reading Flw0. The local leak management device 12 transmits an analog signal corresponding to a voltage value to the water valve 16 to control the flow rate at the inlet of the cold plate 17. In other embodiments, the local leak management device 12 may be connected to the first liquid detector S1, the second liquid detectors S2 and S2′, the third liquid detector S3, the flow meters 19, 19′, and 190, and the water valve 16 through any means applicable of signal transmission.

According to the liquid cooling system with leakage protection and method for cooling liquid leak protection of the second embodiment, by obtaining the detection results of the liquid detectors through the local leak management device and correspondingly outputting the leakage notifications to the central leak management device, the central leak management device may collect sufficient information to determine the corresponding protective measures.

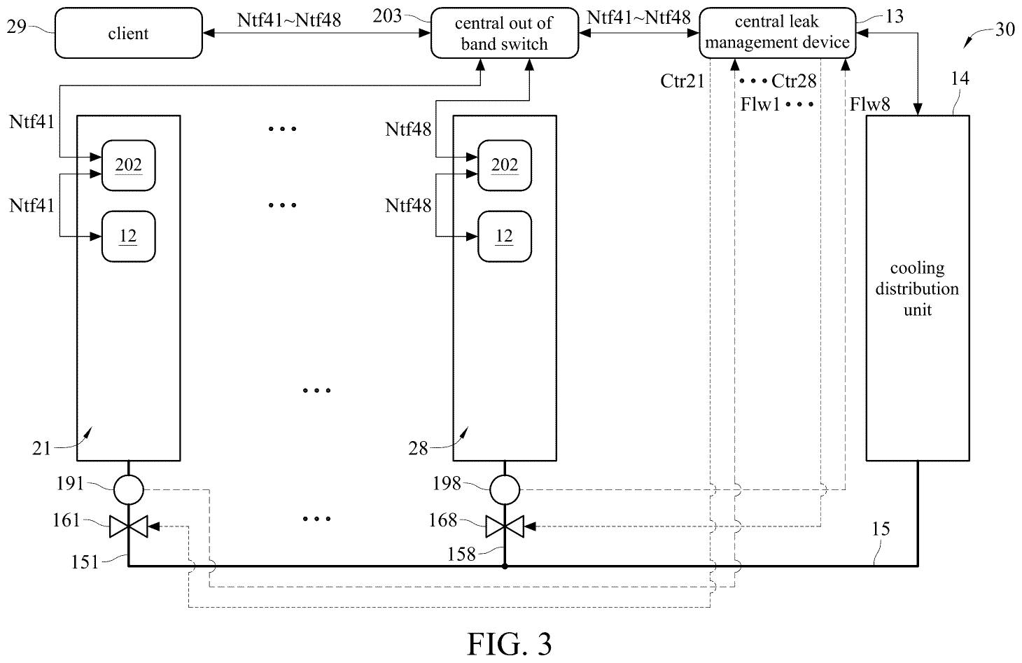

Please refer to FIG. 3, which is a block diagram of a liquid cooling system 30 with leakage protection and the server systems 21 . . . 28 according to the third embodiment of the present disclosure. In FIGS. 1 to 3, substantially identical, similar, or equivalent components are denoted by the same reference numerals, and related details are not repeated herein. The liquid cooling system 30 includes a plurality of flow meters 191 . . . 198 and a plurality of water valves 161 . . . 168. The flow meters 191 . . . 198 are respectively disposed in a plurality of branches 151 . . . 158 of the manifold 15, connected to the central leak management device 13, and configured to generate a plurality of flow rate readings Flw1 . . . Flw8 to the central leak management device 13. The water valves 161 . . . 168 are respectively disposed on the branches 151 . . . 158 of the manifold 15, connected to the central leak management device 13, and controlled by a plurality of second control signals Ctr21 . . . Ctr28 outputted by the central leak management device 13 to adjust opening sizes of the water valves 161 . . . 168.

Compared to the liquid cooling system 20 in FIG. 2, the flow meters 191 . . . 198 and the water valves 161 . . . 168 in the liquid cooling system 30 in FIG. 3 communicate directly with the central leak management device 13, so that the related information (that is, the flow rate readings Flw1 . . . Flw8, the flow anomaly notifications Ntf41 . . . Ntf48, and the second control signals Ctr21 . . . Ctr28) has different transmission paths. Specifically, in the second embodiment of FIG. 2, the flow meter 19 transmits the flow rate reading Flw to the local leak management device 12; the local leak management device 12 outputs the second control signal Ctr2 to close the water valve 16 and transmits the flow anomaly notification Ntf4 to the local OOB switch 202 according to the flow rate reading Flw. Then, the flow anomaly notification Ntf4 is forwarded via the central OOB switch 203 to the central leak management device 13 and the client 29. In the third embodiment of FIG. 3, the flow meter 191 disposed in the server system 21 transmits the flow rate reading Flw1 to the central leak management device 13. The central leak management device 13 outputs the second control signal Ctr2 to close the water valve 161, and outputs the flow anomaly notification Ntf41 according to the flow rate reading Flw1. The flow anomaly notification Ntf41 is forwarded via the central OOB switch 203 to the local OOB switch 202 and the client 29. Then, the flow anomaly notification Ntf41 is forwarded via the local OOB switch 202 to the local leak management device 12.

The liquid cooling system 30 is configured to provide cooling service to the server systems 21 . . . 28. In this case, the flow meters 191 . . . 198 transmit the flow rate readings Flw1 . . . Flw8 to the central leak management device 13. The central leak management device 13 outputs at least one of the second control signals Ctr21 . . . Ctr28 to close at least one of the water valves 161 . . . 168 and outputs at least one of the flow anomaly notifications Ntf41. . . . Ntf48 to the central OOB switch 203 according to at least one of the flow rate readings Flw1 . . . Flw8. The at least one of the flow anomaly notifications Ntf41 . . . Ntf48 forwarded via the central OOB switch 203 is forwarded to at least one of the local OOB switches 202 and client 29. Then, the at least one of the flow anomaly notifications

Ntf41 . . . Ntf48 is forwarded to at least one of the local leak management devices 12 via the local OOB switch 202. Noticeably, under the configuration of the third embodiment, the liquid cooling system 30 may execute the corresponding protective measures with the second shortest delay time when a coolant leakage occurs.

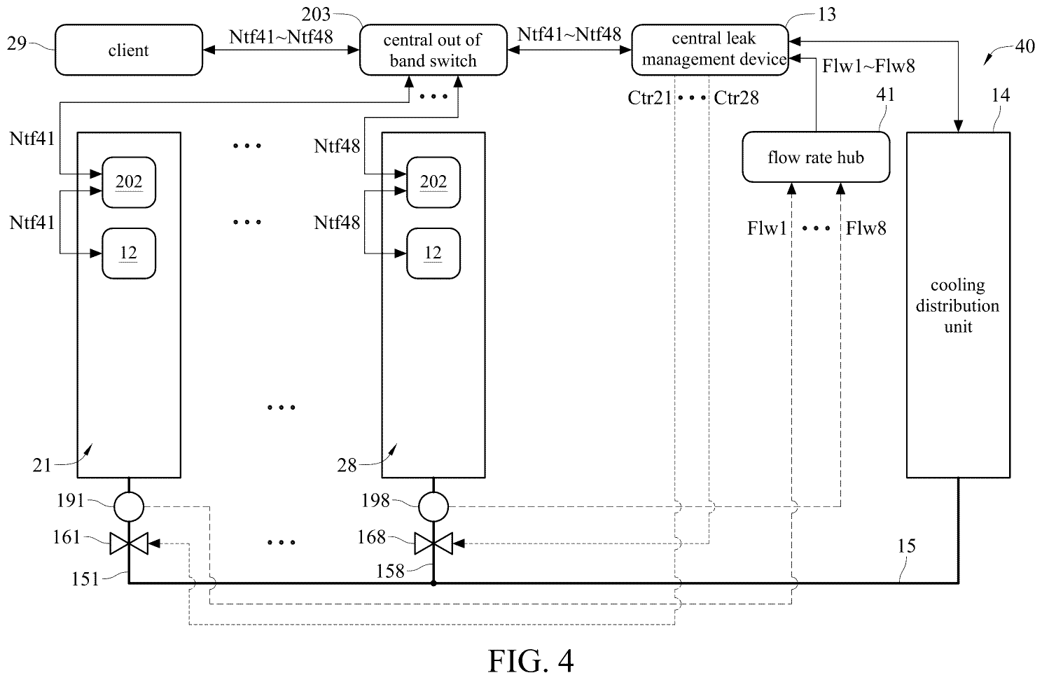

Please refer to FIG. 4, which is a block diagram of a liquid cooling system 40 with leakage protection and the server systems 21 . . . 28 according to the fourth embodiment of the present disclosure. In FIGS. 1 to 4, substantially identical, similar, or equivalent components are denoted by the same reference numerals, and related details are not repeated herein. Compared to the liquid cooling system 30 in FIG. 3, the liquid cooling system 40 in FIG. 4 further includes a flow rate hub 41. The flow rate hub 41 is connected between the flow meters 191 . . . 198 and the central leak management device 13, and is configured to forward the flow rate readings Flw1 . . . Flw8 to the central leak management device 13. Noticeably, under the configuration of the fourth embodiment, the liquid cooling system 40 may execute the corresponding protective measures with the third shortest delay time when a coolant leakage occurs.

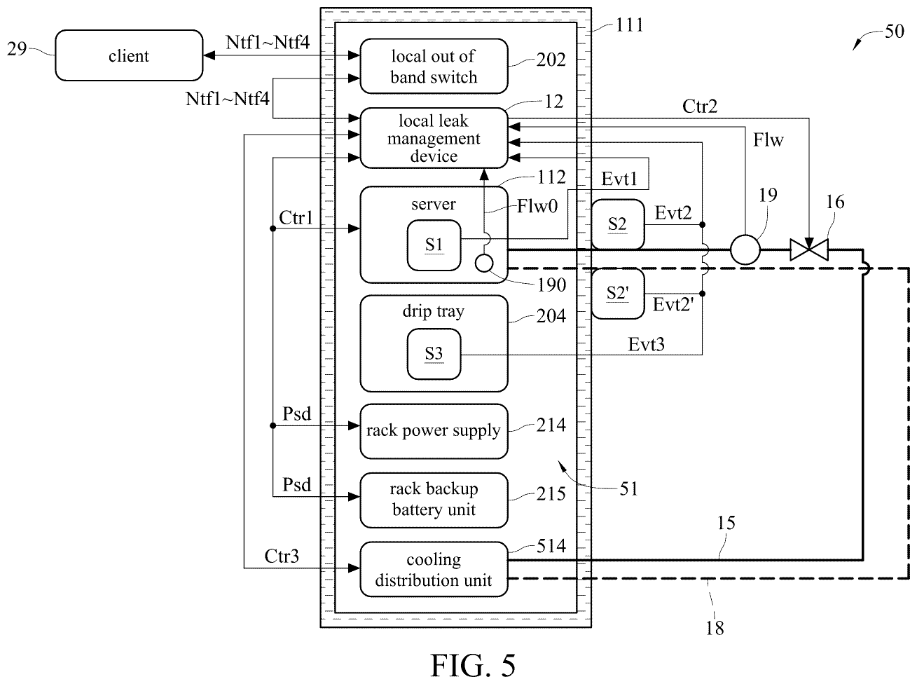

Please refer to FIG. 5, which is block diagram of a liquid cooling system 50 with leakage protection and a server system 51 according to the fifth embodiment of the present disclosure. In FIGS. 1 to 5, substantially identical, similar, or equivalent components are denoted by the same reference numerals, and related details are not repeated herein. Compared to liquid cooling systems 10, 20, 30, and 40, the liquid cooling system 50 only serves one server system 51, requiring less coolant and lower pumping power. Therefore, the CDU 514 is disposed inside the rack 111, this configuration is also referred to as “in-rack CDU.”

The CDU 514 includes a pumping unit, configured to distribute coolant to the cold plate 17 via the manifold 15 and water valve 16 (shown in FIG. 1), where the cold plate 17 is disposed within the server 112 and configured to cool the server 112. The first liquid detector S1 is disposed within the server 112, and configured to detect the server leakage event Evt1. The local leak management device 12 is disposed within the rack 111, connected to the first liquid detector S1, and configured to control the server 112 to shut down after data archiving, close the water valve 16, and control the pumping unit to reduce the flow rate distributed to the cold plate 17 upon receiving the server leakage event Evt1.

The manifolds 15 and 18 are connected between the CDU 514 and the cold plate 17, and configured to transmit the coolant. The second liquid detectors S2 and S2′ are disposed on the manifolds 15 and 18, and configured to detect the manifold leakage events

Evt2 and Evt2′. The drip tray 204 is disposed within the rack 11. The third liquid detector S3 is disposed within the drip tray 204 and configured to detect the tray leakage event Evt3. The local leak management device 12 is further configured to control the server 112 to enter the standby mode after data archiving, close the water valve 16, and control the pumping unit to reduce the flow rate distributed to the cold plate 17 upon receiving at least one of the manifold leakage events Evt2, Evt2′ and the tray leakage event Evt3.

The flow meter 19 is disposed within the manifold 15 located outside the server 112, configured to generate the flow rate reading Flw outside the server 112 to the local leak management device 12. The flow meter 190 is disposed within the manifold 15 located inside the server 112, and configured to generate the flow rate reading Flw0 within the server 112 to the local leak management device 12. The local leak management device 12 is further configured to control the server 112 to enter the standby mode after data archiving, close the water valve 16, and control the pumping unit to reduce the flow rate distributed to the cold plate 17 when determining that at least one of the flow rate readings Flw and Flw0 is lower than the preset flow rate.

The liquid cooling system 50 is configured to serve the client 29. The local OOB switch 202 is connected to the local leak management device 12, and is configured to forward at least one of the server leak notification Ntf1, the manifold leakage notification Ntf2, the tray leakage notification Ntf3, and the flow anomaly notification Ntf4 from the local leak management device 12 to the client 29. The local leak management device 12 is further configured to output at least one of the server leak notification Ntf1, the manifold leakage notification Ntf2, the tray leakage notification Ntf3, and the flow anomaly notification Ntf4 upon receiving at least one of the server leakage event Evt1, the manifold leakage events Evt2, Evt2′, the tray leakage event Evt3, and the flow anomaly notification Ntf4.

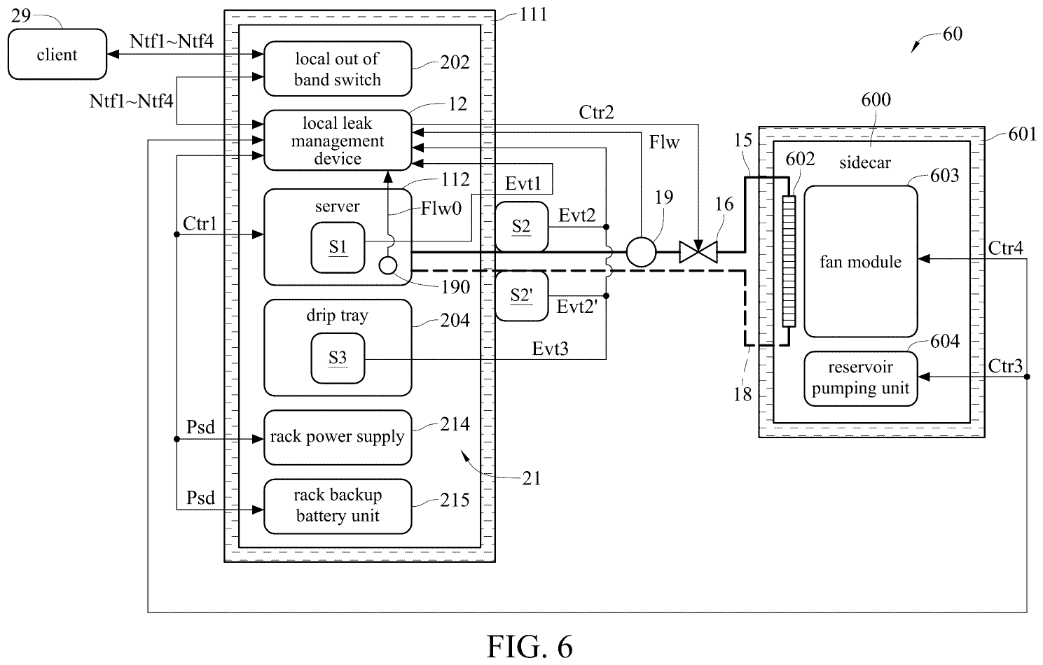

Please refer to FIG. 6, which is a block diagram of a liquid cooling system 60 with leakage protection and a server system 21 according to the sixth embodiment of the present disclosure. In FIGS. 1 to 6, substantially identical, similar, or equivalent components are denoted by the same reference numerals, and related details are not repeated herein. Compared to the liquid cooling systems 20 and 50, a sidecar 600 of the liquid cooling system 60 may replace the CDUs 14 and 514. The sidecar 600 is disposed outside the rack 111, and is configured to distribute the coolant to the cold plate 17 (shown in FIG. 1) via the manifold 15 and the water valve 16. The sidecar 600 includes a casing 601, a heat sink 602, a fan module 603, and a reservoir pumping unit (RPU) 604. The heat sink 602 is connected to the manifold 18 of the outlet of the cold plate 17, and is configured to dissipate heat from the coolant for temperature reduction. The fan module 603 is disposed inside the casing 601, connected to the local leak management device 12, and configured to blow air over the heat sink 602 according to the fourth control signal Ctr4, to adaptively adjust heat dissipation efficiency. The reservoir pumping unit 604 is disposed inside the casing 601, connected to the local leak management device 12 and the inlet of the cold plate 17, and configured to adjust the pumping power according to the third control signal Ctr3, to adjust the flow rate of the coolant entering the cold plate 17.

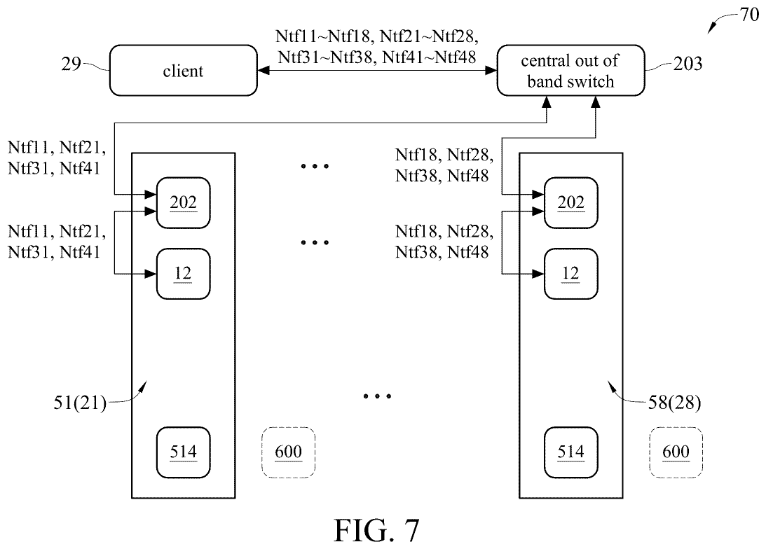

Please refer to FIG. 7, which is a block diagram of a liquid cooling system 70 with leakage protection and a plurality of server systems 51 . . . 58 according to the seventh embodiment of the present disclosure. The liquid cooling system 70 is configured to provide cooling service to the server systems 51 . . . 58. The hardware configurations of the server systems 51 . . . 58 may be the same as or different from each other. In other embodiments, the number of the server systems served by the liquid cooling system 70 is not limited. In FIGS. 1 to 7, substantially identical, similar, or equivalent components are denoted by the same reference numerals, and related details are not repeated herein.

Compared to the liquid cooling system 50, the liquid cooling system 70 is applicable to the server systems 51 . . . 58 or 21 . . . 28 and further includes the central OOB switch 203. The central OOB switch 203 is connected to a plurality of local OOB switches 202 of the server systems 51 . . . 58 or 21 . . . 28. At least one of the local leak management devices 12 of the server systems 51 . . . 58 or 21 . . . 28 generates at least one of the server leak notifications Ntf11 . . . Ntf18, the manifold leakage notifications Ntf21 . . . N tf28, the tray leakage notifications Ntf31 . . . Ntf38, and the flow anomaly notifications Ntf41 . . . Ntf48 to at least one of the plurality of local OOB switches 202 when at least one of the leakage event and the flow rate anomaly is detected. Then, at least one of the plurality of local OOB switches 202 forwards at least one of the server leak notifications Ntf11 . . . Ntf18, the manifold leakage notifications Ntf21 . . . Ntf28, the tray leakage notifications Ntf31 . . . Ntf38, and the flow anomaly notifications Ntf41 . . . Ntf48 to the client 29. In an embodiment, at least one sidecar 600 may replace at least one CDU 514 of the liquid cooling system 70.

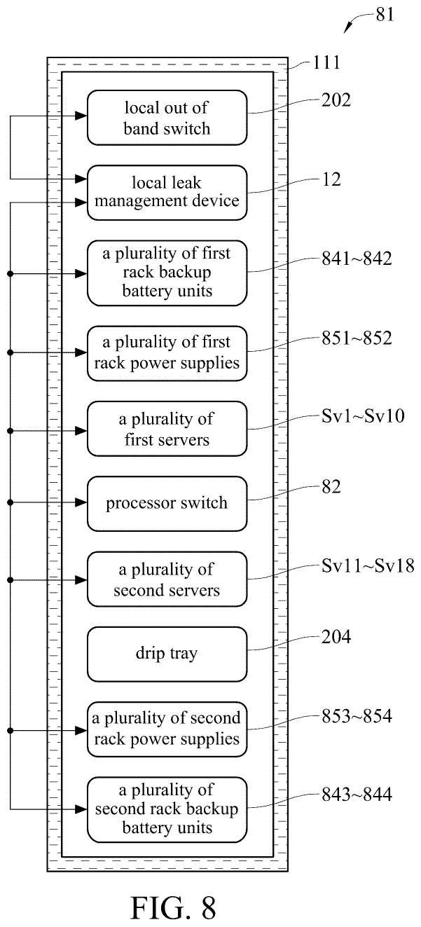

Please refer to FIG. 8, which is a block diagram of a server system 81 according to the eighth embodiment of the present disclosure. The server system 81 may replace at least one of the server systems 11, 21 . . . 28, and 51 . . . 58 in FIGS. 1 to 7. In FIGS. 1 to 8, substantially identical, similar, or equivalent components are denoted by the same reference numerals, and related details are not repeated herein. The server system 81 includes a rack 111, a plurality of first rack backup battery units 841 and 842, a plurality of first rack power supplies 851 and 852, a plurality of first servers Sv1 . . . Sv10, a processor switch 82, a plurality of second servers Sv11 . . . Sv18, a plurality of second rack power supplies 853 and 854, and a plurality of second rack backup battery units 843 and 844. The above electronic components, the local OOB switch 202, the local leak management device 12, and the drip tray 204 are disposed within the rack 111. In multiple embodiments, at least one of the first servers Sv1 . . . Sv10, the processor switch 82, and the second servers Sv11 . . . Sv18 may replace the server 112 in FIGS. 1, 2, 5, and 6.

In practical applications, as computing power demand increases, the number of computing units built into the server system 81 (e.g., central processing units, graphics processing units, parallel computing units, etc.) increases, leading to higher power consumption. Accordingly, the server system 81 is configured with two sets of the computing subsystems Sv1 . . . Sv10 and Sv11 . . . Sv18, two sets of the rack backup battery units 841 . . . 844, and two sets of the rack power supplies 851 . . . 854.

Structurally, the processor switch 82 is disposed and connected between the first servers Sv1 . . . Sv10 and the second servers Sv11 . . . Sv18, and is configured to exchange data between the two server subsystems Sv1 . . . Sv10 and Sv11 . . . Sv18. The first rack power supplies 851 and 852 are disposed adjacent to and connected to the first servers Sv1 . . . Sv10, and configured to supply power to the first servers Sv1 . . . Sv10. The first rack backup battery units 841 and 842 are disposed adjacent to the first rack power supplies 851 and 852, connected to the first servers Sv1 . . . Sv10, and configured to provide backup power to the first servers Sv1 . . . Sv10.

On the other hand, the second rack power supplies 853 and 854 are disposed adjacent to and connected to the second servers Sv11 . . . Sv18, and configured to supply power to the second servers Sv11 . . . Sv18. The second rack backup battery units 843 and 844 are disposed adjacent to the second rack power supplies 853 and 854, connected to the second servers Sv11 . . . Sv18, and configured to provide backup power to the second servers Sv11 . . . Sv18.

It should be noted that the drip tray 204 is disposed between the second servers Sv11 . . . Sv18 and the second rack power supplies 853 and 854. In other words, the drip tray 204 may block the leaked coolant from flowing, due to gravity, to the second rack power supplies 853 and 854 and the second rack backup battery units 843 and 844 disposed below.

Additionally, there are two of the first rack backup battery units, the second rack backup battery units, the first rack power supplies, and the second rack power supplies, ten of the first servers and eight of the second servers, as shown in FIG. 8. However, the quantities are only examples, and the present disclosure does not limit the quantities of the first rack backup battery unit, the second rack backup battery unit, the first rack power supply, the second rack power supply, the first server, and the second server.

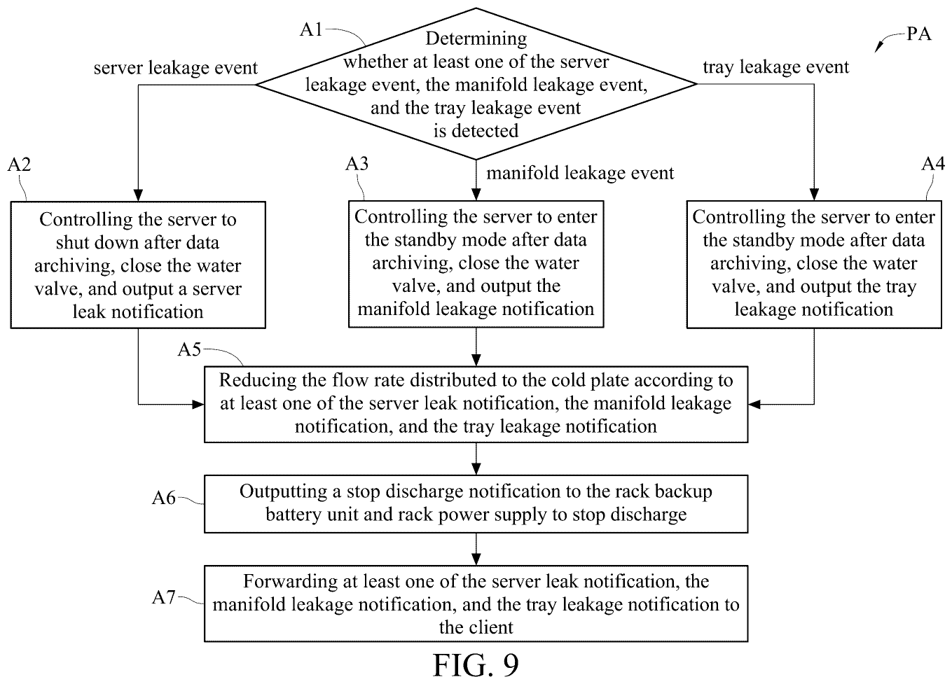

The operations of the liquid cooling systems 10, 20, 30, 40, 50, 60, and 70 may be summarized as the coolant leakage protection procedures PA and PB, which may be performed simultaneously. As shown in FIG. 9, the coolant leakage protection procedure PA includes the following steps.

Step A1: Determining whether at least one of the server leakage event, the manifold leakage event, and the tray leakage event is detected. If the server leakage is detected, proceed to step A2; if the manifold leakage event is detected, proceed to step A3; if the tray leakage event is detected, proceed to step A4.

Step A2: Controlling the server to shut down after data archiving, close the water valve, and output a server leak notification when the server leakage event is detected. Proceed to step A5.

Step A3: Controlling the server to enter the standby mode after data archiving, close the water valve, and output the manifold leakage notification when the manifold leakage event is detected. Proceed to step A5.

Step A4: Controlling the server to enter the standby mode after data archiving, close the water valve, and output the tray leakage notification when the tray leakage event is detected. Proceed to step A5.

Step A5: Reducing the flow rate distributed to the cold plate according to at least one of the server leak notification, the manifold leakage notification, and the tray leakage notification. Step A5 comprises: controlling the CDU or reservoir pumping unit to reduce the flow rate distributed to the cold plate according to at least one of the server leak notification, the manifold leakage notification, and the tray leakage notification.

Step A6: Outputting the stop discharge notification to the rack backup battery unit and rack power supply to stop discharge.

Step A7: Forwarding at least one of the server leak notification, the manifold leakage notification, and the tray leakage notification to the client.

It should also be noted that FIG. 9 illustrates the coolant leak protection procedure PA as executing steps A5, A6, and A7 in sequence. However, the execution sequence of steps A5, A6, and A7 may be interchangeable, and multiple steps among steps A5, A6, and A7 may be executed simultaneously. The present disclosure does not limit the execution sequence of steps A5, A6, and A7.

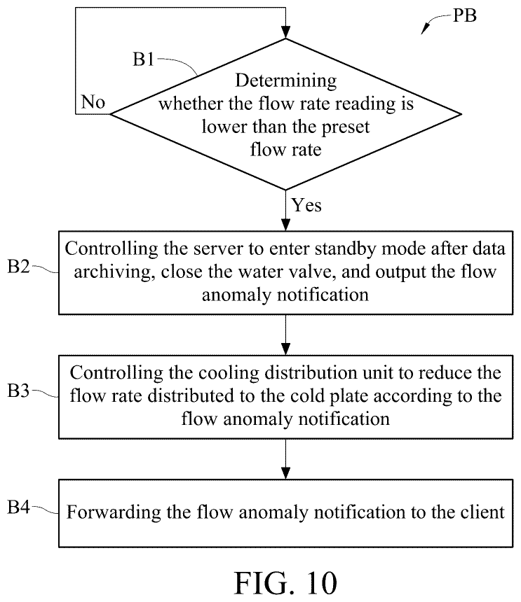

As shown in FIG. 10, the coolant leak protection procedure PB includes the following steps.

Step B1: Determining whether the flow rate reading is lower than the preset flow rate. If yes, proceed to step B2; if no, return to step B1.

Step B2: Controlling the server to enter the standby mode after data archiving, close the water valve, and output the flow anomaly notification.

Step B3: Controlling the CDU to reduce the flow rate distributed to the cold plate according to the flow anomaly notification.

Step B4: Forwarding the flow anomaly notification to the client.

It should be noted that in FIG. 10, the coolant leakage protection procedure PB is illustrated as executing steps B3 and B4 in sequence. However, the execution sequence between steps B3 and B4 may be interchangeable, and steps B3 and B4 may also be executed simultaneously. The present disclosure does not limit the execution sequence of steps B3 and B4.

In the first embodiment of FIG. 1, steps A1 . . . A4, A6, B1, and B2 are executed by the local leak management device 12, and steps A5, A7, B3, and B4 are executed by the central leak management device 13.

In the second embodiment of FIG. 2, the local leak management device 12 executes steps A1 . . . A4, A6, B1, and B2, the central leak management device 13 executes steps A5 and B3, and the local OOB switch 202 and the central OOB switch 203 execute steps A7 and B4. The coolant leak protection procedure PA further includes: between steps A2 . . . A4 and A5, the local OOB switch 202 and the central OOB switch 203 forward at least one of the server leakage notification, the manifold leakage notification, and the tray leakage notification to the central leak management device 13. The coolant leak protection procedure PB further includes: between steps B3 and B4, the local OOB switch 202 and the central OOB switch 203 forward the flow anomaly notification to the central leak management device 13.

Compared to the second embodiment in FIG. 2, in the third embodiment in FIG. 3, the central leak management device 13 executes steps A2 . . . A4 to close the water valve and steps B1 . . . B3.

Compared to the third embodiment in FIG. 3, in the fourth embodiment in FIG. 4, the coolant leakage protection procedure PB further includes: the flow rate hub forwarding the flow rate readings Flw1 . . . Flw8 to the central leak management device 13 before step B1.

In the fifth embodiment in FIG. 5 and the sixth embodiment in FIG. 6, steps A1 . . . A 6 and B1 . . . B3 are executed by the local leak management device 12, and steps A7 and B4 are executed by the local OOB switch 202.

Compared to the fifth embodiment in FIG. 5, in the seventh embodiment in FIG. 7, steps A7 and B4 are executed by the central OOB switch 203. The coolant leakage protection procedure PA further includes: between steps A6 and A7, the local OOB switch 202 forwards at least one of the server leakage notification, the manifold leakage notification, and the tray leakage notification to the central OOB switch 203. The coolant leakage protection procedure PB further includes: between steps B3 and B4, the local OOB switch 202 forwards the flow anomaly notification to the central OOB switch 203. In the embodiments of the present disclosure, the coolant leakage protection procedures PA and PB may be compiled into program codes and stored in the memory of the local leak management device 12 and the memory of the central leak management device 13 to instruct the processors built into the local leak management device 12 and the central leak management device 13 to execute the related steps. The processor may be, for example, a central processing unit, a graphics processing unit, a microcontroller, a programmable logic controller, or other processors with signal processing capabilities, or combinations thereof, but the present disclosure is not limited thereto. The memory may be, for example, a read-only memory (ROM), a flash memory, a random access memory (RAM), a hard disk, an optical data storage device, a non-volatile storage unit, or combinations thereof, but the present disclosure is not limited thereto.

In view of the above description, the liquid cooling system with leakage protection and method for cooling liquid leak protection of the present disclosure have the following features: (1) automated mitigation mechanism that reduces the need for manual intervention and improves the system's self-protection capability to extend the lifespan of the server system; (2) protection of client's data asset: the automated mitigation mechanism minimizes hardware damage under leakage condition, promptly notifies the client and the machine to perform data archiving, thereby extending the equipment's lifespan; (3) the statuses of all components may be integrated through the setup of the local leak management device and the central leak management device, and in the event of a coolant leakage, the corresponding protective measures may be executed with the shortest delay; and (4) through the detection results obtained by the local leak management device from the liquid detectors, and correspondingly outputting the leakage notifications to the central leak management device, the central leak management device may collect sufficient information to determine the corresponding protective measures.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A liquid cooling system with leakage protection, which is applicable to a server system comprising a rack and a server disposed within the rack, comprising:
a cooling distribution unit disposed outside the rack and configured to distribute a coolant to a cold plate via a manifold and a water valve, wherein the cold plate is disposed within the server and configured to cool the server;
a first liquid detector disposed within the server and configured to detect a server leakage event;
a local leakage management device disposed within the rack, connected to the first liquid detector, and configured to control the server to shut down after data archiving, close the water valve, and output a server leakage notification, upon receiving the server leakage event; and
a central leakage management device connected to the local leakage management device and configured to control the cooling distribution unit to reduce a flow rate distributed to the cold plate according to the server leakage notification.

2. The liquid cooling system with leakage protection according to claim 1, further comprising:
the manifold connected between the cooling distribution unit and the cold plate, and configured to transmit the coolant; and
a second liquid detector disposed on the manifold and configured to detect a manifold leakage event;
wherein the local leakage management device is further configured to control the server to enter a standby mode after data archiving, close the water valve, and output a manifold leakage notification to the central leakage management device upon receiving the manifold leakage event;
wherein the central leakage management device is further configured to control the cooling distribution unit to reduce the flow rate distributed to the cold plate according to the manifold leakage notification.

3. The liquid cooling system with leakage protection according to claim 2, further comprising:
a drip tray disposed within the rack; and
a third liquid detector disposed within the drip tray and configured to detect a tray leakage event;
wherein the local leakage management device is further configured to control the server to enter the standby mode after data archiving, close the water valve, and output a tray leakage notification to the central leakage management device upon receiving the tray leakage event;
wherein the central leakage management device is further configured to control the cooling distribution unit to reduce the flow rate distributed to the cold plate according to the tray leakage notification.

4. The liquid cooling system with leakage protection according to claim 3, wherein the server system includes a rack power supply and a rack backup battery unit, the local leakage management device is further configured to, after outputting at least one of the server leakage notification, the manifold leakage notification and the tray leakage notification, output a stop discharge notification to the rack power supply and the rack backup battery unit, wherein a power management controller and an alternating current power interface of the server system remain in operation.

5. The liquid cooling system with leakage protection according to claim 3, further comprising:
a local out of band switch connected to the local leakage management device, configured to forward at least one of the server leakage notification, the manifold leakage notification and the tray leakage notification from the local leakage management device.

6. The liquid cooling system with leakage protection according to claim 5, configured to serve a client, the liquid cooling system further comprising:
a central out of band switch connected between the local out of band switch, the client and the central leakage management device, and configured to forward at least one of the server leakage notification, the manifold leakage notification, and the tray leakage notification from the local out of band switch to the client and the central leakage management device.

7. The liquid cooling system with leakage protection according to claim 1, further comprising:
a first flow meter disposed within the manifold located outside the server, and configured to generate a first flow reading to the local leakage management device;
a second flow meter disposed within the manifold located inside the server, and configured to generate a second flow reading to the local leakage management device;
wherein the local leakage management device is further configured to control the server to enter a standby mode after data archiving, close the water valve, and output a flow anomaly notification to the central leakage management device when determining that at least one of the first flow reading and the second flow reading is below a preset flow rate; and
the central leakage management device is further configured to control the cooling distribution unit to reduce the flow rate distributed to the cold plate of the server according to the flow anomaly notification.

8. The liquid cooling system with leakage protection according to claim 6, applicable to a plurality of the server system, and the liquid cooling system further comprising:
a plurality of flow meters respectively disposed within a plurality of branches of the manifold, connected to the central out of band switch, and configured to generate a plurality of flow readings to the central leakage management device; and
a plurality of water valves respectively disposed on the plurality of branches of the manifold, and connected to the central out of band switch;
wherein the central leakage management device is further configured to close at least one of the plurality of water valves and output at least one of a plurality of flow anomaly notifications to the central out of band switch according to at least one of the plurality of flow readings.

9. The liquid cooling system with leakage protection according to claim 8, further comprising:
a flow hub connected between the plurality of flow meters and the central leakage management device, and configured to forward the plurality of flow readings to the central leakage management device.

10. The liquid cooling system with leakage protection according to claim 3, wherein the server system includes a plurality of first rack backup battery units, a plurality of first rack power supplies, a plurality of first servers, a processor switch, a plurality of second servers, a plurality of second rack power supplies and a plurality of second rack backup battery units, wherein:
the processor switch is disposed and connected between the plurality of first servers and the plurality of second servers;
the plurality of first rack power supplies are disposed adjacent to and connected to the plurality of first servers;
the plurality of first rack backup battery units are disposed adjacent to the plurality of first rack power supplies and connected to the plurality of first servers;
the plurality of second rack power supplies are disposed adjacent to and connected to the plurality of second servers;
the plurality of second rack backup battery units are disposed adjacent to the plurality of second rack power supplies and connected to the plurality of second servers; and
the drip tray is disposed between the plurality of second servers and the plurality of second rack power supplies.

11. A liquid cooling system with leakage protection, which is applicable to a server system comprising a rack and a server disposed within the rack, comprising:
a pumping unit disposed within the rack, and configured to distribute coolant to a cold plate via a manifold and a water valve, wherein the cold plate is disposed within the server and configured to cool the server;
a first liquid detector disposed within the server and configured to detect a server leakage event; and
a local leakage management device disposed within the rack, connected to the first liquid detector, and configured to control the server to shut down after data archiving, close the water valve, and control the pumping unit to reduce the flow rate distributed to the cold plate, upon receiving the server leakage event.

12. The liquid cooling system with leakage protection according to claim 11, further comprising:
the manifold connected between the cooling distribution unit and the cold plate, and configured to transmit the coolant;
a second liquid detector disposed on the manifold and configured to detect a manifold leakage event;
a drip tray disposed within the rack; and
a third liquid detector disposed within the drip tray and configured to detect a tray leakage event;
wherein the local leakage management device is further configured to control the server to enter a standby mode after data archiving, close the water valve, and control the pumping unit to reduce a flow rate distributed to the cold plate upon receiving at least one of the manifold leakage event and the tray leakage event.

13. The liquid cooling system with leakage protection according to claim 11, further comprising
a first flow meter disposed within the manifold located outside the server, and configured to generate a first flow reading to the local leakage management device;
a second flow meter disposed within the manifold located inside the server, and configured to generate a second flow reading to the local leakage management device;
wherein the local leakage management device is further configured to control the server to enter a standby mode after data archiving, close the water valve, and control the pumping unit to reduce the flow rate distributed to the cold plate when determining that at least one of the first flow reading and the second flow meter reading is below a preset flow rate.

14. The liquid cooling system with leakage protection according to claim 13, configured to serve a client, and the liquid cooling system further comprising:
a local out of band switch connected to the local leakage management device, and configured to forward at least one of a server leakage notification, a manifold leakage event, a tray leakage event and a flow anomaly notification from the local leakage management device to the client;
wherein the local leakage management device is further configured to output at least one of the server leakage notification, the manifold leakage event, the tray leakage notification and the flow anomaly notification upon receiving at least one of the server leakage event, the manifold leakage event and the tray leakage event.

15. The liquid cooling system with leakage protection according to claim 14, applicable to a plurality of the server systems, and the liquid cooling system further comprising:
a central out of band switch connected between a plurality of the local out of band switches of the plurality of server systems and the client, and configured to forward at least one of a plurality of the server leakage notifications, a plurality of the manifold leakage notifications, a plurality of the tray leakage notifications and a plurality of the flow anomaly notifications from the plurality of the local out of band switches to the client.

16. The liquid cooling system with leakage protection according to claim 11, further comprising a sidecar, wherein the sidecar comprises:
a casing;
a heatsink disposed within the casing and connected to the cold plate, and configured to dissipate heat from the coolant for temperature reduction;
a fan module disposed within the casing and configured to blow air over the heatsink to adaptively adjust heat dissipation efficiency of the heatsink; and
the pumping unit disposed within the casing and connected to the local leakage management device, and configured to adjust power to regulate a flow rate of the coolant.

17. A coolant leakage protection method, which is applicable to a server system, the server system comprising a rack and a server disposed within the rack, comprising:
controlling the server to shut down after data archiving, closing a water valve of the server and outputting a server leakage notification upon detecting a server leakage event; and
reducing a flow rate distributed to a cold plate disposed within the server according to the server leakage notification.

18. The coolant leakage protection method according to claim 17, further comprising:
controlling the server to enter a standby mode after data archiving, closing the water valve and outputting a manifold leakage notification upon detecting a manifold leakage event; and reducing the flow rate distributed to the cold plate according to the manifold leakage notification.

19. The coolant leakage protection method according to claim 18, further comprising:
controlling the server to enter the standby mode after data archiving, closing the water valve, and outputting a tray leakage notification to the central leakage management device upon detecting a tray leakage event; and
reducing the flow rate distributed to the cold plate according to the tray leakage notification.

20. The coolant leakage protection method according to claim 19, further comprising:
outputting a stop discharge notification to a rack power supply and a rack backup battery unit of the server system after outputting at least one of the server leakage notification, the manifold leakage notification and the tray leakage notification.
wherein a power management controller and an alternating current power interface of the server system remain in operation.

21. The coolant leakage protection method of claim 19, further comprising:
controlling the server to enter the standby mode after data archiving, close the water valve and output a flow anomaly notification upon detecting a flow reading below a preset flow rate; and
reducing the flow rate distributed to the cold plate according to the flow anomaly notification.

22. The coolant leakage protection method of claim 21, wherein the server system is configured to serve a client, and the method further comprises:
forwarding at least one of the server leakage notification, the manifold leakage notification, the tray leakage notification and the flow anomaly notification to the client.
